(19) United States
(12) Patent Application Publication
(10) Pub. No.: US 2006/0279446 A1
(43) Pub. Date: Dec. 14, 2006

(54) Method and apparatus for RF signal demodulation

(75) Inventors: Chung-Cheng Wang, Taipei County (TW); John-San Yang, Hsinchu County (TW)

Correspondence Address: BIRCH STEWART KOLASCH & BIRCH, PO BOX 747, FALLS CHURCH, VA, 22040-0747, US

(73) Assignee: Airoha Technology Corp.

(21) Appl. No.: 11/451,362

(22) Filed: Jun. 13, 2006

(30) Foreign Application Priority Data
Jun. 13, 2005 (TW) 94119468

(51) Int. Cl. H03M 1/12

(52) U.S. Cl. 341/155

(57) ABSTRACT

A radio frequency (RF) receiver is provided, comprising an antenna, a low noise amplifier, a down converter, a first analog to digital converter (ADC), a second ADC, a digital up converter. The antenna receives an RF signal, and the LNA coupled to the antenna amplifies the RF signal. The down converter, coupled to the LNA, down converts the RF signal to generate an in-phase baseband signal and a quadrature baseband signal. The first ADC, coupled to the down converter, digitizes the in-phase baseband signal to an in-phase digital signal. The second ADC, coupled to the down converter, digitizes the quadrature baseband signal to a quadrature digital signal. The digital up converter, coupled to the first and second ADCs, up converts the in-phase digital signal and quadrature digital signal to generate an intermediate frequency (IF) signal.

### BACKGROUND

The invention relates to RF reception, and in particular, to a method for generating an IF signal from an RF signal.

FIG. 1 shows a conventional super heterodyne receiver. An antenna 101 receives a radio frequency (RF) signal. A low noise amplifier (LNA) 102 amplifies the RF signal, and a first band pass filter (BPF) 103 filters the RF signal to eliminate unnecessary components therein. A mixer 104 converts the frequency of the RF signal based on an oscillation frequency generated from a local oscillator (OSC) 105 to generate an intermediate frequency (IF) signal comprising image components. A second BPF 106 filters the IF signal to eliminate unnecessary image components and outputs a pure IF signal. The oscillation frequency generated by the local OSC 105 determines the frequency of the IF signal. The super heterodyne architecture is compact, providing excellent channel selection capability, while avoiding adjacent band signal interference. The first BPF 103 and second BPF 106, however, are costly to implement due to high quality and high accuracy requirements, therefore conventional filters are implemented externally.

FIG. 2 shows a conventional zero intermediate frequency (ZIF) receiver, a currently popular architecture through which RF signals are directly converted to baseband without IF stages. In FIG. 2, an antenna 101 receives an RF signal and a LNA 102 amplifies the RF signal. Thereafter, a direct conversion unit 210 converts the RF signal directly to generate an in-phase baseband signal B_{I} and a quadrature baseband signal BQ. The direct conversion unit 210 comprises a local OSC 105, an in-phase mixer 202, a quadrature mixer 204, a first low pass filter (LPF) 206 and a second LPF 208. The local OSC 105 generates a cosine wave and a sinusoidal wave. The frequencies of the waves are identical to the carrier frequency of the RF signal. The in-phase mixer 202 multiplies the output of the LNA 102 by the cosine wave, generating a result comprising in-phase baseband signal B_{I} and image components. The quadrature mixer 204 also multiplies the output of LNA 102 by the sinusoidal wave to obtain quadrature baseband signal B_{Q} and image components. The first LPF 206 and second LPF 208 filter out the image components to reserve the in-phase baseband signal B_{I} and quadrature baseband signal B_{Q}. The ZIF design, while simple, cannot be adopted for situations requiring IF signals. Thus, an additional demodulator is desirable to generate the required IF signal from the ZIF receiver.

### SUMMARY

An exemplary radio frequency (RF) receiver is provided, comprising an antenna, a low noise amplifier, a down converter, a first analog to digital converter (ADC), a second ADC and a digital up converter. The antenna receives an RF signal, and the LNA coupled to the antenna amplifies the RF signal. The down converter, coupled to the LNA, down converts the RF signal to generate an in-phase baseband signal and a quadrature baseband signal. The first ADC, coupled to the down converter, digitizes the in-phase baseband signal to an in-phase digital signal. The second ADC, coupled to the down converter, digitizes the quadrature baseband signal to a quadrature digital signal. The digital up converter, coupled to the first and second ADCs, up converts the in-phase digital signal and quadrature digital signal to generate an intermediate frequency (IF) signal.

The down converter comprises a local oscillator (OSC), an in-phase mixer, a quadrature mixer, a first low pass filter (LPF) and a second LPF. The local OSC generates a sinusoidal wave and a cosine wave. The in-phase mixer, coupled to the LNA and the local OSC, multiplies the RF signal by the cosine wave. The quadrature mixer, coupled to the LNA and the local OSC, multiplies the RF signal by the sinusoidal wave. The LPF, coupled to the in-phase mixer, filters the output therefrom to obtain the in-phase baseband signal. The second LPF, coupled to the quadrature mixer, filters the output therefrom to obtain the quadrature baseband signal. The frequency of the sinusoidal and cosine wave may be equal to the RF signal carrier frequency. Alternatively, the frequency of the sinusoidal and cosine wave may be equal to the RF signal carrier frequency plus a predetermined offset.

The digital up converter comprises a digital local OSC, an in-phase digital up converter, a quadrature digital up converter, a digital adder and a digital limiter. The digital local OSC generates an IF cosine wave and an IF sinusoidal wave. The in-phase digital up converter, coupled to the digital local OSC, receives and multiplies the in-phase digital signal with the IF cosine wave. The quadrature digital up converter, coupled to the digital local OSC, receives and multiplies the quadrature digital signal with the IF sinusoidal wave. The digital adder, coupled to the in-phase and quadrature digital up converters, sums output from the in-phase and quadrature digital up converters. The digital limiter, coupled to the digital adder, quantizes the output from the digital adder to generate the IF signal. The IF sinusoidal wave and the IF cosine wave are 10.8 MHz, and the IF signal is a 10.8 MHz square wave.

Another embodiment of the invention provides a demodulation method, comprising the following steps. A RF signal is received and amplified, and down converted to baseband to generate an in-phase baseband signal and a quadrature baseband signal. The in-phase baseband signal and quadrature baseband signal are digitized to obtain an in-phase digital signal and a quadrature digital signal. The in-phase digital signal and quadrature digital signal are up converted to intermediate frequency, generating an IF signal.

### BRIEF DESCRIPTION OF THE DRAWINGS

The following detailed description, given by way of example and not intended to limit the invention solely to the embodiments described herein, will best be understood in conjunction with the accompanying drawings, in which:

FIG. 1 shows a conventional super heterodyne receiver;

FIG. 2 shows a conventional zero intermediate frequency (ZIF) receiver;

FIGS. 3a and 3b show embodiments of the RF receiver according to the invention;

FIG. 4 shows an embodiment of the digital up converter;

FIG. 5 shows another embodiment of the digital up converter; and

FIG. 6 is a flowchart of the demodulation method.

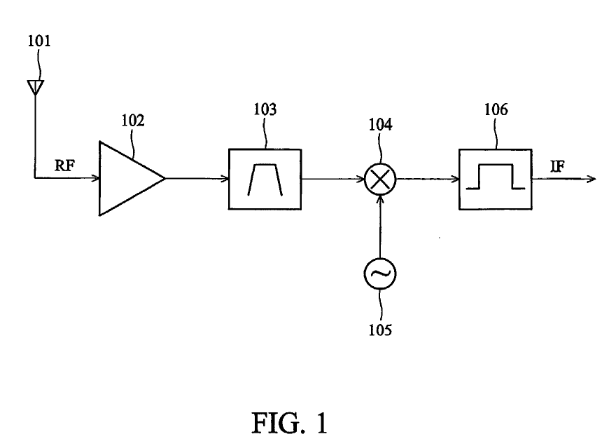

### DETAILED DESCRIPTION

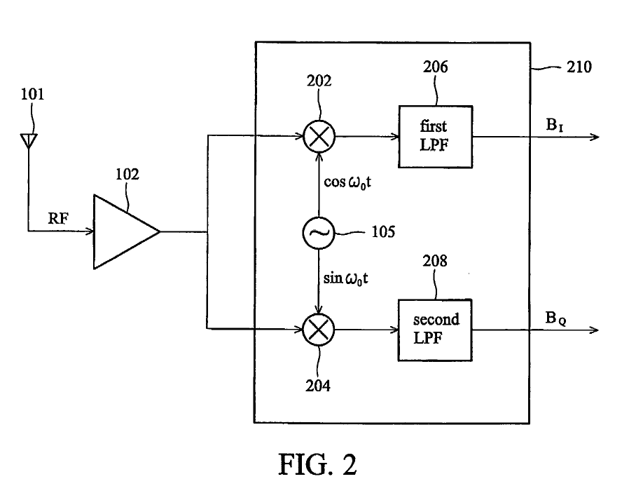

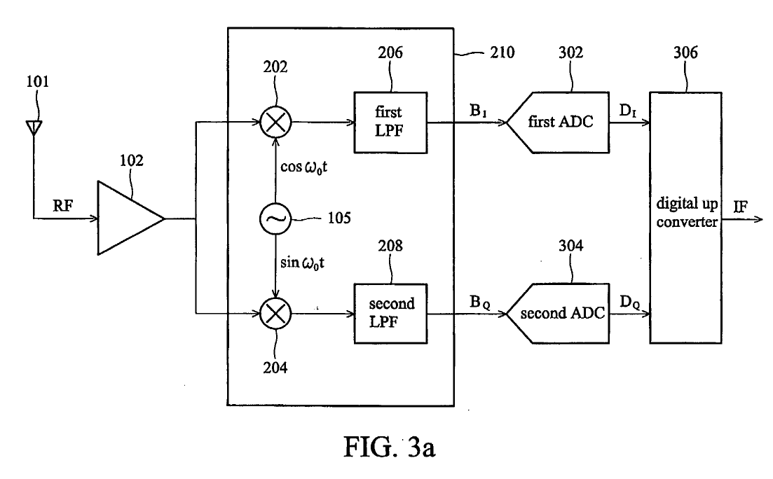

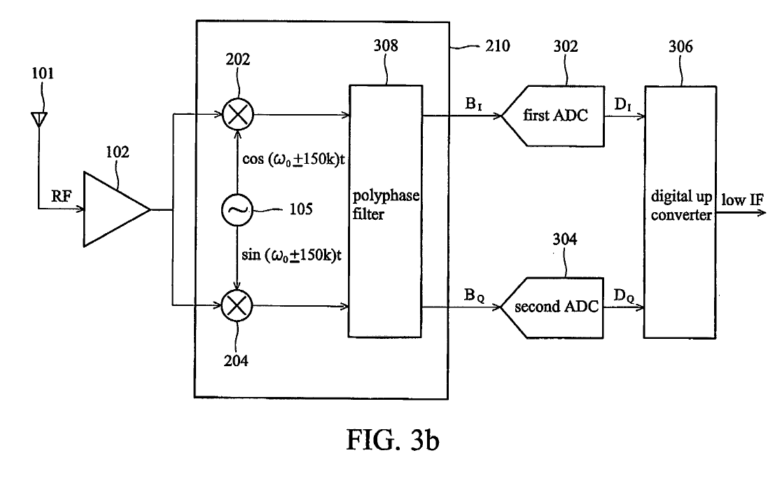

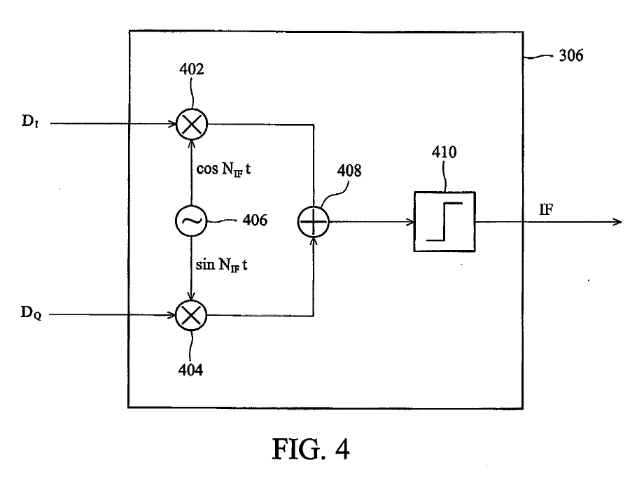

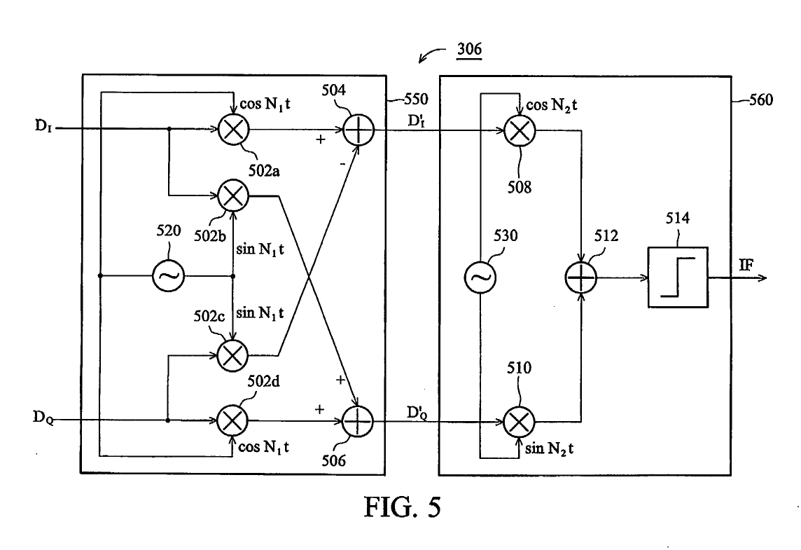

FIGS. 3a and 3b show embodiments of the RF receiver according to the invention. In FIG. 3a, the antenna 101, LNA 102 and direct conversion unit 210 are identical to the ZIF receiver in FIG. 2. In-phase baseband signal B_{I} and quadrature baseband signal B_{Q} are generated from the direct conversion unit 210, and then digitized by the first ADC 302 and second ADC 304 to generate corresponding in-phase digital signal D_{I} and quadrature digital signal D_{Q}. Thereafter, a digital up converter 306 combines the in-phase digital signal D_{I} and quadrature digital signal D_{Q} into the IF signal. The embodiment is based on conventional ZIF architecture, thus possesses good image rejection capability. A detailed description of the digital up converter 306 is disclosed in FIG. 4 and FIG. 5.

In FIG. 3b, the direct conversion unit 220 differs from the direct conversion unit 210 in FIG. 3a, in that local OSC 105 provides an oscillation frequency different from the RF carrier frequency. For example, if the oscillation frequency is ω₀±150K and ω₀ is the carrier frequency of the RF signal, the in-phase baseband signal B_{I} and quadrature baseband signal B_{Q} are distributed close to the baseband but are not equal thereto. Thus, DC offset caused by image components is avoided. The architecture in FIG. 3b is also referred to as a very low intermediate frequency (VLIF) architecture, having better signal strength than the ZIF architecture in FIG. 3a. The direct conversion unit 220 comprises a polyphase filter 308 having excellent image rejection capability, such that the in-phase baseband signal B_{I} and quadrature baseband signal B_{Q} are generated. Identically, the first ADC 302 and second ADC 304 digitize the in-phase baseband signal B_{I} and quadrature baseband signal B_{Q} to generate an in-phase digital signal D_{I} and a quadrature digital signal D_{Q}, and the digital up converter 306 combines the in-phase digital signal D_{I} and the quadrature digital signal D_{Q} to an IF signal.

FIG. 4 shows an embodiment of the digital up converter 306. When the in-phase digital signal D_{I} and quadrature digital signal D_{Q} are input to the digital up converter 306, an in-phase digital up converter 402 and a quadrature digital up converter 404 up convert the frequencies thereof. A digital local OSC 406 generates an IF cosine wave and an IF sinusoidal wave for conversion of the in-phase digital signal D_{I} and the quadrature digital signal D_{Q} in the in-phase digital up converter 402 and the quadrature digital up converter 404. A digital adder 408 sums the output from the in-phase digital up converter 402 and the quadrature digital up converter 404, and a digital limiter 410 quantizes the output from the digital adder 408 to generate the IF signal. The digital limiter 410 is a quantizer capable of converting input signals to square waves, functioning equivalent to a limiter for analog signals.

FIG. 5 shows another embodiment of the digital up converter 306. The digital up converter 306 performs up conversion of the in-phase digital signal D_{I} and quadrature digital signal D_{Q} in two stages. The first stage is performed in the first up mixer 550, and the second stage takes place in the second up mixer 560. The first up mixer 550 comprises four multipliers, 502a to 502d, a first local OSC 520, a first adder 504 and a second adder 506. The first local OSC 520 generates a first sinusoidal wave and a first cosine wave. The first multiplier 502a multiplies the in-phase digital signal D_{I} by the first cosine wave, the second multiplier 502b multiplies the in-phase digital signal D_{I} by the first sinusoidal wave, the third multiplier 502c multiplies the quadrature digital signal D_{Q} by the first sinusoidal wave, and the fourth multiplier 502d multiplies the quadrature digital signal D_{Q} by the first cosine wave. The first adder 504, coupled to the first multiplier 502a and third multiplier 502c, subtracts the output of third multiplier 502c from the output of first multiplier 502a to generate the in-phase digital low frequency signal D′_{I}. The second adder 506, coupled to the second multiplier 502b and fourth multiplier 502d, sums the output of the second multiplier 502b and the fourth multiplier 502d to generate the quadrature digital low frequency signal D′_{Q}. The process in the first up mixer 550 is also referred to as complex mixing, and thereby the in-phase digital signal D_{I} and quadrature digital signal D_{Q} are up converted to 1.2 MHz, forming the in-phase digital low frequency signal D′_{I} and the quadrature digital low frequency signal D′_{Q}. The first sinusoidal wave and the first cosine wave are 1.2 MHz.

The second up mixer 560 comprises a second local OSC 530 generating second cosine and sinusoidal waves. A fifth multiplier 508 coupled to the second local OSC 530, multiplies the in-phase digital low frequency signal D′_{I} by the second cosine wave. A fifth multiplier 508, coupled to the second local OSC 530, multiplies the quadrature digital low frequency signal D′_{Q} by the second sinusoidal wave. A third adder 512, coupled to the fifth multiplier 508 and the sixth multiplier 510, sums the output from the fifth multiplier 508 and sixth multiplier 510 and outputs the result to a digital limiter 514. The digital limiter 514 may be a 1-bit quantizer generating square wave IF signals. In this embodiment, the second sinusoidal and cosine waves are 9.6 MHz. By up converting the 1.2 MHz signals with 9.6 MHz, the resultant IF signal turns out to be a 10.8 MHz square wave. The advantage of the two stage up conversion is that the second local OSC 530 can have built-in 9.6 MHz frequency without additional oscillator, and the 1.2 MHz can be generated from a lookup table. Thus, no additional hardware is required to generate the 10.8 MHz frequency, and cost is reduced.

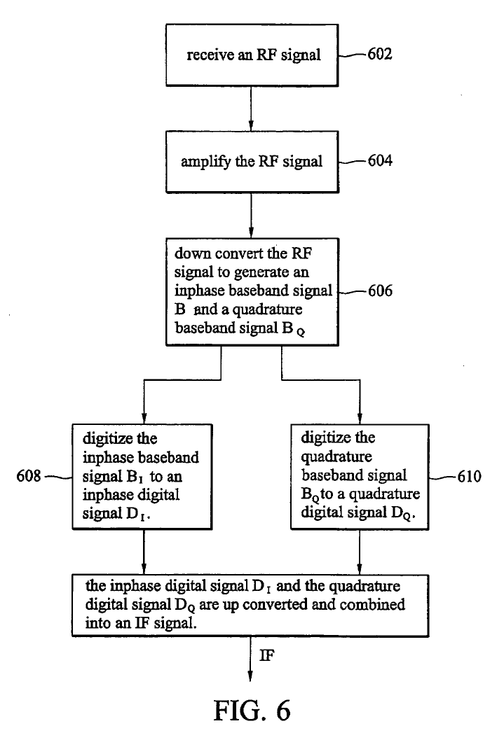

FIG. 6 is a flowchart of the demodulation method. First, in step 602, an RF signal is received. In step 604, the RF signal is amplified. In step 606, the RF signal is down converted to generate an in-phase baseband signal B_{I} and a quadrature baseband signal B_{Q}. In step 608 and 610, the in-phase baseband signal B_{I} and quadrature baseband signal B_{Q} are digitized to an in-phase digital signal D_{I} and a quadrature digital signal DQ. In step 612, the in-phase digital signal D_{I} and the quadrature digital signal D_{Q} are up converted and combined into an IF signal.

In the down conversion, the RF signal may be down converted to the baseband or a very low frequency such as 150 KHz. In the up conversion, the in-phase digital signal D_{I} and quadrature digital signal D_{Q} may be up converted to the IF signal directly, or up converted in two stages. For example, the signal can first be up converted to 1.2 MHz, and then up converted by 9.6 MHz to generate the 10.8 MHz IF. The first up conversion can be a complex mixing process that directly rejects image components, such as the process performed in the first local OSC 520 in FIG. 5.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A radio frequency (RF) receiver, comprising:
an antenna, receiving an RF signal;
a low noise amplifier (LNA), coupled to the antenna, amplifying the RF signal;
a down converter, coupled to the LNA, down converting the RF signal to generate an in-phase baseband signal and a quadrature baseband signal;
a first analog to digital converter (ADC), coupled to the down converter, digitizing the in-phase baseband signal to an in-phase digital signal;
a second analog to digital converter (ADC), coupled to the down converter, digitizing the quadrature baseband signal to a quadrature digital signal; and
a digital up converter, coupled to the first and second ADCs, up converting the in-phase digital signal and quadrature digital signal to generate an intermediate frequency (IF) signal.

2. The RF receiver as claimed in claim 1, wherein the down converter comprises:
a local oscillator (OSC), generating a sinusoidal wave and a cosine wave;
an in-phase mixer, coupled to the LNA and the local OSC, multiplying the RF signal by the cosine wave;
a quadrature mixer, coupled to the LNA and the local OSC, multiplying the RF signal by the sinusoidal wave;
a first low pass filter (LPF), coupled to the in-phase mixer and filtering the output therefrom to obtain the in-phase baseband signal; and
a second LPF, coupled to the quadrature mixer and filtering the output therefrom to obtain the quadrature baseband signal; wherein the frequency of the sinusoidal and cosine wave are equal to the RF signal carrier frequency.

3. The RF receiver as claimed in claim 1, wherein the down converter comprises:
a local oscillator (OSC), generating a sinusoidal wave and a cosine wave;
an in-phase mixer, coupled to the LNA and the local OSC, converting the RF signal by the cosine wave;
a quadrature mixer, coupled to the LNA and the local OSC, converting the RF signal by the sinusoidal wave;
a polyphase filter coupled to the in-phase mixer and the quadrature mixer, the polyphase filter outputting the in-phase baseband signal and the quadrature baseband signal; wherein the frequency of the sinusoidal and cosine wave are equal to the RF signal carrier frequency plus a predetermined offset.

4. The RF receiver as claimed in claim 1, wherein the digital up converter comprises:
a digital local OSC, generating an IF cosine wave and an IF sinusoidal wave;
an in-phase digital up converter, coupled to the digital local OSC, receiving and multiplying the in-phase digital signal and the IF cosine wave;
a quadrature digital up converter, coupled to the digital local OSC, receiving and multiplying the quadrature digital signal and the IF sinusoidal wave;
a digital adder, coupled to the in-phase and quadrature digital up converters, adding the outputs from the in-phase and quadrature digital up converters; and
a digital limiter, coupled to the digital adder, quantizing the output from the digital adder to generate the IF signal.

5. The RF receiver as claimed in claim 1, wherein the IF sinusoidal wave and the IF cosine wave are 10.8 MHz, and the IF signal is a 10.8 MHz square wave.

6. The RF receiver as claimed in claim 1, wherein the digital up converter comprises:
a first up converter, receiving the in-phase digital signal and the quadrature digital signal, performing complex mixing to up convert the frequency of the in-phase digital signal and quadrature digital signal, generating a in-phase digital low frequency signal and a quadrature digital low frequency signal;
a second up converter, comprising:
a second local OSC, generating a second cosine wave and a second sinusoidal wave;
a fifth multiplier, coupled to the second local OSC, receiving the in-phase digital low frequency signal and the second cosine wave, outputting the multiplication of the in-phase digital low frequency signal and the second cosine wave;
a sixth multiplier, coupled to the second local OSC, receiving the quadrature digital low frequency signal and the second sinusoidal wave, outputting the multiplication of the quadrature digital low frequency signal and the second sinusoidal wave;
a third adder, coupled to the fifth multiplier and the sixth multiplier, outputting the sum of output from the fifth and sixth multiplier; and
a digital limiter, coupled to the third adder, quantizing the output from the third adder to generate the IF signal.

7. The RF receiver as claimed in claim 6, wherein the first up converter comprises:
a first local OSC, generating a first sinusoidal wave and a first cosine wave;
a first multiplier, coupled to the first local OSC, receiving and multiplying the in-phase digital signal and the first cosine wave;
a second multiplier, coupled to the first local OSC, receiving and multiplying the in-phase digital signal and the first sinusoidal wave;
a third multiplier, coupled to the first local OSC, receiving and multiplying the quadrature digital signal and the first sinusoidal wave;
a fourth multiplier, coupled to the first local OSC, receiving and multiplying the quadrature digital signal and the first cosine wave;
a first adder, coupled to the first multiplier and the third multiplier, subtracting the output of third multiplier from the output of the first multiplier to generate the in-phase digital low frequency signal; and
a second adder, coupled to the second and fourth multiplier, summing the output of the second and fourth multipliers to generate the quadrature digital low frequency signal.

8. The RF receiver as claimed in claim 7, wherein:
the first sinusoidal and cosine waves are 1.2 MHz;
the second sinusoidal and cosine waves are 9.6 MHz; and
the IF signal is a 10.8 MHz square wave.

9. A demodulation method, comprising:
receiving and amplifying an RF signal;
down converting the RF signal to baseband to generate an in-phase baseband signal and a quadrature baseband signal;
digitizing the in-phase baseband signal and quadrature baseband signal to obtain an in-phase digital signal and quadrature digital signal; and
up converting the in-phase digital signal and quadrature digital signal to an intermediate frequency, thus generating an IF signal.

10. The demodulation method as claimed in claim 9, wherein the down conversion comprises:
generating a sinusoidal wave and a cosine wave;
multiplying the RF signal by the cosine wave to obtain an in-phase result;
multiplying the RF signal by the sinusoidal wave to obtain a quadrature result;
filtering the in-phase result to obtain the in-phase baseband signal; and
filtering the quadrature result to obtain the quadrature baseband signal; wherein the frequency of the sinusoidal and cosine wave are equal to the RF signal carrier frequency.

11. The demodulation method as claimed in claim 9, wherein the down conversion comprises:
generating a sinusoidal wave and a cosine wave;
multiplying the RF signal by the cosine wave to obtain an in-phase result;
multiplying the RF signal by the sinusoidal wave to obtain a quadrature result;
filtering the in-phase result to obtain the in-phase baseband signal; and
filtering the quadrature result to obtain the quadrature baseband signal; wherein the frequency of the sinusoidal and cosine wave are equal to the RF signal carrier frequency plus a predetermined offset.

12. The demodulation method as claimed in claim 9, wherein the up conversion comprises:
generating an IF cosine wave and an IF sinusoidal wave;
multiplying the in-phase digital signal and the IF cosine wave;
multiplying the quadrature digital signal and the IF sinusoidal wave;
adding the in-phase digital signal and quadrature digital signal multiplication results; and
quantizing the sum to obtain the IF signal.

13. The demodulation method as claimed in claim 9, wherein the IF sinusoidal wave and the IF cosine wave are 10.8 MHz, and the IF signal is a 10.8 MHz square wave.

14. The demodulation method as claimed in claim 9, wherein the up conversion comprises:
performing complex mixing to up convert the frequency of the in-phase digital signal and quadrature digital signal, generating an in-phase digital low frequency signal and a quadrature digital low frequency signal;
generating a second cosine wave and a second sinusoidal wave;
multiplying the in-phase digital low frequency signal and the second cosine wave;
multiplying the quadrature digital low frequency signal and the second sinusoidal wave;
summing the multiplication results of the in-phase digital low frequency signal and quadrature digital low frequency signal; and
quantizing the sum to generate the IF signal.

15. The demodulation method as claimed in claim 9, wherein the complex mixing comprises:
generating a first sinusoidal wave and a first cosine wave;
multiplying the in-phase digital signal and the first cosine wave to generate a first digital signal;
multiplying the in-phase digital signal and the first sinusoidal wave to generate a second digital signal;
multiplying the quadrature digital signal and the first sinusoidal wave to generate a third digital signal;
multiplying the quadrature digital signal and the first cosine wave to generate a fourth digital signal;
subtracting the third digital signal from the first digital signal to generate the in-phase digital low frequency signal; and
summing the second and fourth digital signals to generate the quadrature digital low frequency signal.

16. The demodulation method as claimed in claim 15, wherein:
the first sinusoidal and cosine waves are 1.2 MHz;
the second sinusoidal and cosine waves are 9.6 MHz; and
the IF signal is a 10.8 MHz square wave.
